(19) United States
(12) Patent Application Publication
(10) Pub. No.: US 2026/0144133 A1
(43) Pub. Date: May 21, 2026

(54) INNER AND OUTER SEAL RINGS TO ADHERE POLYIMIDE LAYER TO PASSIVATION LAYER ON A SEMICONDUCTOR DIE

(71) Applicant: Microchip Technology Incorporated, Chandler, AZ (US)

(72) Inventors: Robin Liu, Fremont, CA (US); Zhiming Feng, Milpitas, CA (US); Ziyan Xu, San Jose, CA (US); Thomas Krutsick, Fleetwood, PA (US); Pejman Khosropour, Campbell, CA (US); Eleonore Daeman, Trets (FR)

(73) Assignee: Microchip Technology Incorporated, Chandler, AZ (US)

(21) Appl. No.: 18/975,776

(22) Filed: Dec. 10, 2024

Related U.S. Application Data
(60) Provisional application No. 63/721,855, filed on Nov. 18, 2024.

(51) Int. Cl. H01L 23/31; H01L 21/56; H01L 23/29; H01L 23/58

(52) U.S. Cl. CPC H10W 74/147; H10W 42/00; H10W 74/01; H10W 74/47

(57) ABSTRACT

An apparatus, system, and method for a die seal layout design to improve adhesion of a polyimide layer to a passivation layer in semiconductor packaging is disclosed. The apparatus may include an outer seal ring on a semiconductor die. The apparatus may also include an inner seal ring on a portion of the semiconductor die. The apparatus may further include a trench between the outer seal ring and the inner seal ring. The apparatus may include a passivation layer covering the semiconductor die including the outer seal ring and the inner seal ring. The apparatus may additionally include a polyimide layer covering a portion of the passivation layer over the inner seal ring and a portion of the trench.

### PRIORITY

This application claims priority to U.S. Provisional Ser. No. 63/721,855 filed Nov. 18, 2024, the contents of which are hereby incorporated in their entirety.

### TECHNICAL FIELD

The present disclosure relates to adding a polyimide layer on top of a passivation layer during semiconductor packaging, and, in particular, to a die seal layout design to improve adhesion of the polyimide layer to the passivation layer.

### BACKGROUND

Semiconductor packaging is the process of enclosing a semiconductor die within a protective enclosure to facilitate handling, testing, and integration into larger systems. The package provides mechanical support, electrical connections, and environmental protection for the semiconductor. As part of the packaging process, a passivation layer may be added to the semiconductor die. The passivation layer is a protective coating applied to the surface of a semiconductor die to prevent contamination and degradation. For some products, such as analog and power devices with very high voltage capacitors, a polyimide layer may be on top of the passivation layer. Polyimide layers are used in semiconductor packaging due to their electrical, thermal, and mechanical properties. The polyimide layer may have adhesion issues and may detach from the passivation layer, causing isolation and reliability issues.

### SUMMARY OF THE INVENTION

Aspects provide apparatuses, systems, and methods for a die seal layout design to improve adhesion of a polyimide layer to a passivation layer in semiconductor packaging. Examples of the present disclosure may include an apparatus. The apparatus may include an outer seal ring on a semiconductor die. The apparatus may also include an inner seal ring on a portion of the semiconductor die. The apparatus may further include a trench between the outer seal ring and the inner seal ring. The apparatus may include a passivation layer covering the semiconductor die including the outer seal ring and the inner seal ring. The apparatus may additionally include a polyimide layer covering a portion of the passivation layer over the inner seal ring and a portion of the trench.

In combination with any of the above examples, the trench may be created using top metal narrow spacing between a top metal of the outer seal ring and a top metal of the inner seal ring.

In combination with any of the above examples, a portion of the polyimide layer covering the portion of the trench may anchor the polyimide layer to the passivation layer.

In combination with any of the above examples, the outer seal ring and the inner seal ring and side bars may form a grid structure to anchor the polyimide layer to the passivation layer.

In combination with any of the above examples, a sidewall of the trench may have a negative slope.

In combination with any of the above examples, the apparatus may also include a pad opening in the trench between the outer seal ring and the inner seal ring.

In combination with any of the above examples, the pad opening may create a second trench inside the trench.

In combination with any of the above examples, the polyimide layer may fill the second trench.

In combination with any of the above examples, a sidewall of the second trench may have a negative slope.

In combination with any of the above examples, the passivation layer may be planarized and the pad opening creates the trench in the passivation layer.

In combination with any of the above examples, the polyimide layer may fill the trench.

In combination with any of the above examples, a top metal of the outer seal ring and a top metal of the inner seal ring may create a mechanical support for the trench and the polyimide layer to anchor the polyimide layer to the passivation layer.

In combination with any of the above examples, a side bar of a top metal of the outer seal ring may hold a top metal of the inner seal ring.

In combination with any of the above examples, a spacing between the inner seal ring and the outer seal ring may be based on a depth of the passivation layer.

In combination with any of the above examples, a spacing between the inner seal ring and the outer seal ring may be based on a thickness of a top metal of the outer seal ring or a thickness of a top metal of the inner seal ring.

In combination with any of the above examples, a location at which the polyimide layer stops inside the trench may be based on adhesion of the polyimide layer to the passivation layer.

In combination with any of the above examples, the negative slope may be created by a deposition recipe for the passivation layer.

In combination with any of the above examples, the negative slope may be created by a slope of the top metal of the outer seal ring.

In combination with any of the above examples, the negative slope may be created by a slope of the top metal of the inner seal ring.

In combination with any of the above examples, a depth of the second trench may be based on an etch recipe for the pad opening.

In combination with any of the above examples, a depth of the trench may be based on an etch recipe for the pad opening.

In combination with any of the above examples, the negative slope may be created by an etch recipe for the pad opening.

Alone or in combination with any of the above examples, examples of the present disclosure may include a method. The method may include forming an outer seal ring on a semiconductor die. The method may also include forming an inner seal ring on a portion of the semiconductor die. The method may additionally include covering the outer seal ring and the inner seal ring with a passivation layer. The method may additionally include creating a trench between the outer seal ring and the inner seal ring. The method may further include covering a portion of the passivation layer over the inner seal ring and a portion of the trench with a polyimide layer.

In combination with any of the above examples, the method may further include creating the trench using top metal narrow spacing between a top metal of the outer seal ring and a top metal of the inner seal ring.

In combination with any of the above examples, a portion of the polyimide layer may cover the portion of the trench to anchor the polyimide layer to the passivation layer.

In combination with any of the above examples, the method may further include forming a grid structure to anchor the polyimide layer to the passivation layer using the outer seal ring and the inner seal ring and side bars.

In combination with any of the above examples, a sidewall of the trench may have a negative slope.

In combination with any of the above examples, the method may further include placing a pad opening in the trench between the outer seal ring and the inner seal ring.

In combination with any of the above examples, the method may further include creating a second trench inside the trench using the pad opening.

In combination with any of the above examples, the method may further include filling the second trench with the polyimide layer.

In combination with any of the above examples, a sidewall of the second trench may have a negative slope.

In combination with any of the above examples, the passivation layer may be planarized and the pad opening creates the trench in the passivation layer.

In combination with any of the above examples, the method may further include filling the trench with the polyimide layer.

In combination with any of the above examples, the method may further include creating a mechanical support for the trench and the polyimide layer to anchor the polyimide layer to the passivation layer using a top metal of the outer seal ring and a top metal of the inner seal ring.

In combination with any of the above examples, a side bar of a top metal of the outer seal ring may hold a top metal of the inner seal ring.

In combination with any of the above examples, a spacing between the inner seal ring and the outer seal ring may be based on a depth of the passivation layer.

In combination with any of the above examples, a spacing between the inner seal ring and the outer seal ring may be based on a thickness of a top metal of the outer seal ring or a thickness of a top metal of the inner seal ring.

In combination with any of the above examples, a location at which the polyimide layer stops inside the trench may be based on adhesion of the polyimide layer to the passivation layer.

In combination with any of the above examples, the method may further include creating the negative slope using a deposition recipe for the passivation layer.

In combination with any of the above examples, the method may further include creating the negative slope using a slope of the top metal of the outer seal ring.

In combination with any of the above examples, the method may further include creating the negative slope using slope of the top metal of the inner seal ring.

In combination with any of the above examples, a depth of the second trench may be based on an etch recipe for the pad opening.

In combination with any of the above examples, the method may further include creating the negative slope using recipe for the pad opening.

In combination with any of the above examples, a depth of the trench may be based on an etch recipe for the pad opening.

### BRIEF DESCRIPTION OF THE DRAWINGS

The figures illustrate examples of systems and methods for a die seal layout design to improve adhesion of a polyimide layer to a passivation layer in semiconductor packaging.

FIGS. 1A and 1B illustrate top and cross-sectional views, respectively, of a die seal layout design to improve adhesion of the polyimide layer to a passivation layer in semiconductor packaging, according to examples of the present disclosure;

FIGS. 2A and 2B illustrate top and cross-sectional views, respectively, of a die seal layout design to improve adhesion of the polyimide layer to a passivation layer in semiconductor packaging, according to examples of the present disclosure;

FIGS. 3A and 3B illustrate top and cross-sectional views, respectively, of a die seal layout design to improve adhesion of the polyimide layer to a passivation layer in semiconductor packaging, according to examples of the present disclosure;

FIG. 4 illustrates a method performed for creating a die seal layout design to improve adhesion of a polyimide layer to a passivation layer in semiconductor packaging, according to examples of the present disclosure; and

FIG. 5 illustrates a more detailed method performed for creating a die seal layout design to improve adhesion of a polyimide layer to a passivation layer in semiconductor packaging, according to examples of the present disclosure.

The reference number for any illustrated element that appears in multiple different figures has the same meaning across the multiple figures, and the mention or discussion herein of any illustrated element in the context of any particular figure also applies to each other figure, if any, in which that same illustrated element is shown.

### DESCRIPTION

According to an aspect of the invention, a system and method for a die seal layout design to improve adhesion of a polyimide layer to a passivation layer in semiconductor packaging are provided. The polyimide layer in a semiconductor package may have adhesion issues and may detach from the passivation layer and may cause isolation or reliability issues. Adhesion of the polyimide layer to the passivation layer may depend on factors such as, but not limited to, die size, polyimide layer thickness, polyimide bake recipe, and die layout. Previous attempts to improve polyimide adhesion have included optimization of polyimide film thickness and optimizing bake recipes. However, adhesion issues may persist due to die size and layout of the top layers. To solve polyimide adhesion issues, the die seal layout design disclosed herein may be added to the semiconductor die to improve adhesion of the polyimide layer to the passivation layer.

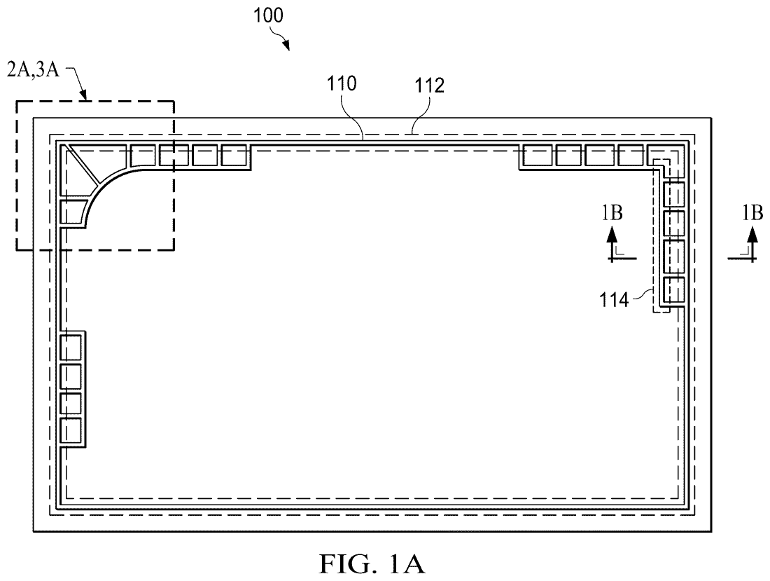

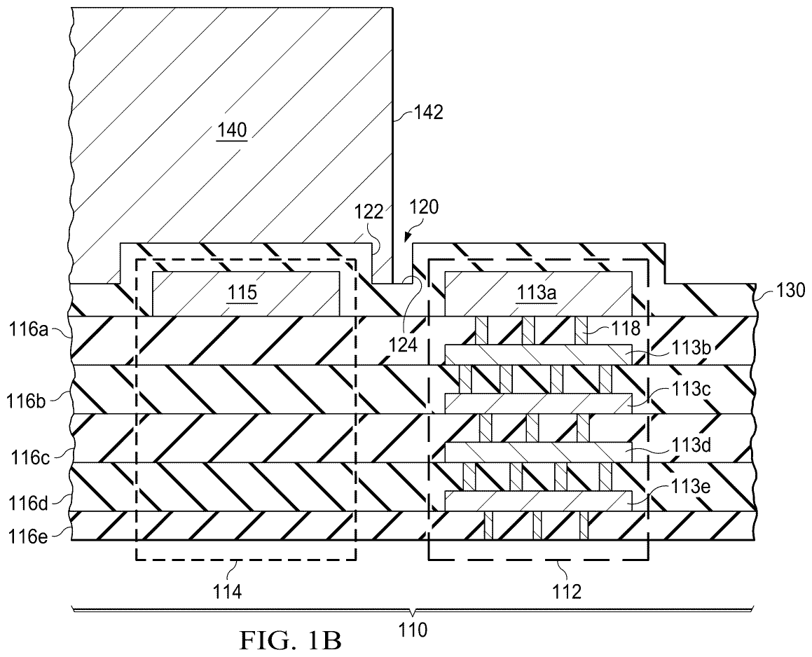

FIGS. 1A and 1B illustrate top and cross-sectional views, respectively, of a die seal layout design to improve adhesion of the polyimide layer to a passivation layer in semiconductor packaging, according to examples of the present disclosure. Semiconductor die 100 may include seal ring 110. Seal ring 110 may be the boundary or outermost part of semiconductor die 100 and may be located between scribe lines and integrated circuits of each die on a wafer.

Seal ring 110 may include outer seal ring 112 and inner seal ring 114. Outer seal ring 112 may be is formed by alternatively laminating dielectric layers 116 and metal layers 113, which are interconnected by vias 118 through dielectric layers 116. Inner seal ring 114 may be formed of metal layer 115 on dielectric layers 116. For example, outer seal ring 112 may be formed of five metal layers 113a, 113b, 113c, 113d, and 113e and inner seal ring 114 may have a single metal layer 115. Metal layer 113a and metal layer 115 may create mechanical support for trench. 120 and polyimide layer 140 to anchor polyimide layer 140 to passivation layer 130. Additionally, the side bar of the top metal layer of outer seal ring 112 (i.e., metal layer 113a) may also hold metal layer 115 of inner seal ring 114 to prevent metal layer 115 from peeling off with polyimide layer 140 in the event polyimide layer 140 detaches from passivation layer 130. While inner seal ring 114 is shown in FIG. 1B as having one metal layer 115, inner seal ring 114 may have any number of metal layers 115 alternating with dielectric layers 116 and interconnected by vias.

The spacing between outer seal ring 112 and inner seal ring 114 may be based on the thickness of metal layer 115 of inner seal ring 114, the thickness of passivation layer 130, or any combination thereof. For example, as the thickness of passivation layer 130 increases, the spacing between outer seal ring 112 and inner seal ring 114 may also increase. In some examples, the spacing between outer seal ring 112 and inner seal ring 114 may be narrow (e.g., 1 to 10 microns (μm)), and the trench may be created using top metal narrow spacing between metal layer 113a and metal layer 115.

Both outer seal ring 112 and inner seal ring 114 may be covered by passivation layer 130. Passivation layer 130 may be non-planarized and may follow the contours of outer seal ring 112 and inner seal ring 114, creating trench 120 between metal layer 113a of outer seal ring 112 and metal layer 115 of inner seal ring 114. While sidewalls 122 of trench 120 are shown in FIG. 1B as being at right angles to floor 124 of trench 120, sidewalls 122 may have a negative slope. The negative slope of sidewalls 122 may further increase the adhesion of polyimide layer 140 to passivation layer 130. The negative slope of sidewalls 122 may be created based on a deposition recipe of passivation layer 130, a slope of the side of metal layer 113a, a slope of the side of metal layer 115, or any combination thereof.

Polyimide layer 140 may be applied on top of passivation layer 130. Polyimide layer 140 may cover a portion of passivation layer 130. For example, polyimide layer 140 may cover a portion of passivation layer 130 and a portion of trench 120 but does not span the entirety of trench 120. Therefore, trench 120 may act as an anchor for polyimide layer 140 to adhere polyimide layer 140 to passivation layer 130, improving the adhesion of polyimide layer 140 to passivation layer 130. Boundary 142 of polyimide layer 140 in trench 120 may be adjusted to improve the adhesion of polyimide layer 140. For example, polyimide layer 140 may cover at least 50% of trench 120. In some examples, polyimide layer 140 may span trench 120 and overlap a portion of passivation layer 130 covering outer seal ring 112.

The grid structure of seal ring 110, including outer seal ring 112 and inner seal ring 114, may provide an array of anchor points to improve the adhesion of polyimide layer 140 to passivation layer 130. While FIG. 1A illustrates the grid structure in select locations along the perimeter of semiconductor die 100, the grid structure may extend along the entire perimeter of semiconductor die 100. In some examples, the grid structure may be interrupted by pad locations on semiconductor die 100.

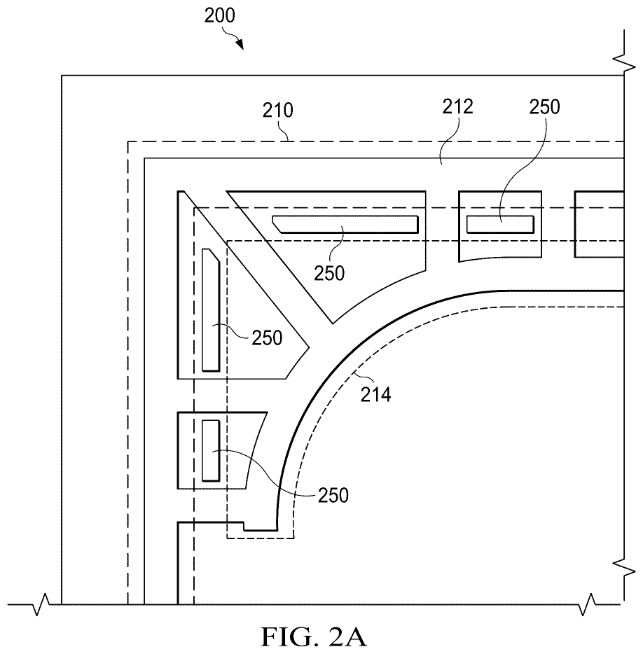

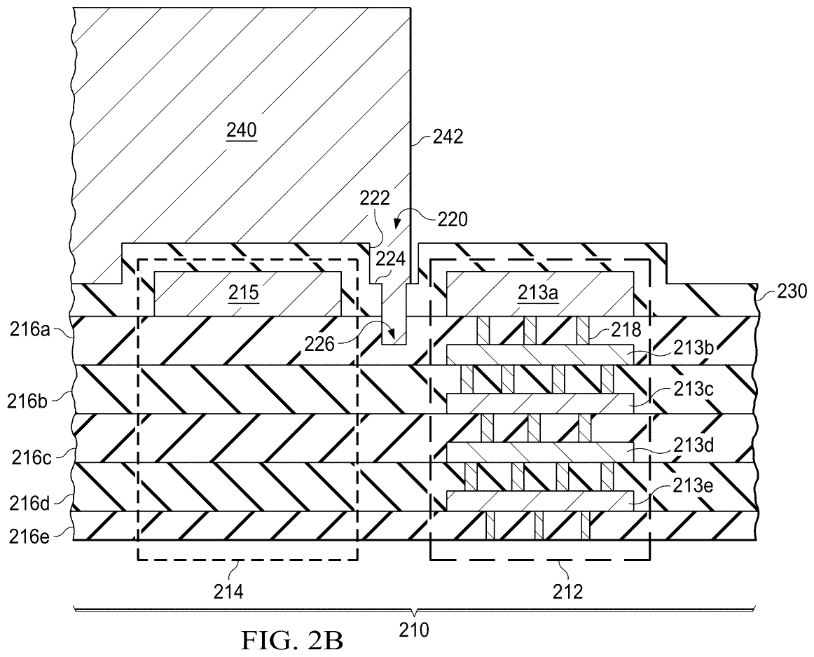

FIGS. 2A and 2B illustrate top and cross-sectional views, respectively, of a die seal layout design to improve adhesion of the polyimide layer to a passivation layer in semiconductor packaging, according to examples of the present disclosure. Semiconductor die 200 and may be located between scribe lines and integrated circuits of each die on a wafer.

Seal ring 210 may include outer seal ring 212 and inner seal ring 214. Outer seal ring 212 may be is formed by alternatively laminating dielectric layers 216 and metal layers 213, which are interconnected by vias 218 through dielectric layers 216. Inner seal ring 214 may be formed of metal layer 215 on dielectric layers 216. For example, outer seal ring 212 may be formed of five metal layers 213a, 213b, 213c, 213d, and 213e and inner seal ring 214 may have a single metal layer 215. Metal layer 213a and metal layer 215 may create mechanical support for trench 220 and polyimide layer 240 to anchor polyimide layer 240 to passivation layer 230. Additionally, the side bar of the top metal layer of outer seal ring 212 (i.e., metal layer 213a) may also hold metal layer 215 of inner seal ring 214 to prevent metal layer 215 from peeling off with polyimide layer 240 in the event polyimide layer 240 detaches from passivation layer 230. While inner seal ring 214 is shown in FIG. 2B as having one metal layer 215, inner seal ring 214 may have any number of metal layers 215 alternating with dielectric layers 216 and interconnected by vias.

The spacing between outer seal ring 212 and inner seal ring 214 may be based on the thickness of metal layer 215 of inner seal ring 214, the thickness of passivation layer 230, or any combination thereof. For example, as the thickness of passivation layer 230 increases, the spacing between outer seal ring 212 and inner seal ring 214 may also increase. In some examples, the spacing between outer seal ring 212 and inner seal ring 214 may be narrow (e.g., 1 to 10 microns (μm)).

Both outer seal ring 212 and inner seal ring 214 may be covered by passivation layer 230. Passivation layer 230 may be non-planarized and may follow the contours of outer seal ring 212 and inner seal ring 214, creating trench 220 between metal layer 213a of outer seal ring 212 and metal layer 215 of inner seal ring 214. While sidewalls 222 of trench 220 are shown in FIG. 2B as being at right angles to floor 224 of trench 220, sidewalls 222 may have a negative slope. The negative slope of sidewalls 222 may further increase the adhesion of polyimide layer 240 to passivation layer 230. The negative slope of sidewalls 222 may be created based on a deposition recipe of passivation layer 230, a slope of the side of metal layer 213a, a slope of the side of metal layer 215, or any combination thereof.

Polyimide layer 240 may be applied on top of passivation layer 230. Polyimide layer 240 may cover a portion of passivation layer 230. For example, polyimide layer 240 may cover a portion of passivation layer 230 and a portion of trench 220 but does not span the entirety of trench 220. Therefore, trench 220 may act as an anchor for polyimide layer 240 to adhere polyimide layer 240 to passivation layer 230, improving the adhesion of polyimide layer 240 to passivation layer 230. Boundary 242 of polyimide layer 240 in trench 220 may be adjusted to improve the adhesion of polyimide layer 240. For example, polyimide layer 240 may cover at least 50% of trench 220. In some examples, polyimide layer 240 may span trench 220 and overlap a portion of passivation layer 230 covering outer seal ring 212.

Trench 220 may be deepened by adding one or more pad openings 250 between outer seal ring 212 and inner seal ring 214. Pad openings 250 may create second trench 226 and increase the depth of a portion of trench 220. The depth of second trench 226 may be controlled by the pad mask and the over etch time, recipe, or any combination thereof used to create pad openings 250. While the sidewalls of second trench 226 are shown in FIG. 2B as being at right angles to the floor of second trench 226, the sidewalls may have a negative slope. The negative slope of the sidewalls may further increase the adhesion of polyimide layer 240 to passivation layer 230. The negative slope of the sidewalls may be created based on a deposition recipe of passivation layer 230, a slope of the side of metal layer 213a, a slope of the side of metal layer 215, or any combination thereof.

The grid structure of seal ring 210, including outer seal ring 212 and inner seal ring 214, may provide an array of anchor points to improve the adhesion of polyimide layer 240 to passivation layer 230. While FIG. 2A illustrates the grid structure in select locations along the perimeter of semiconductor die 200, the grid structure may extend along the entire perimeter of semiconductor die 200. In some examples, the grid structure may be interrupted by pad locations on semiconductor die 200.

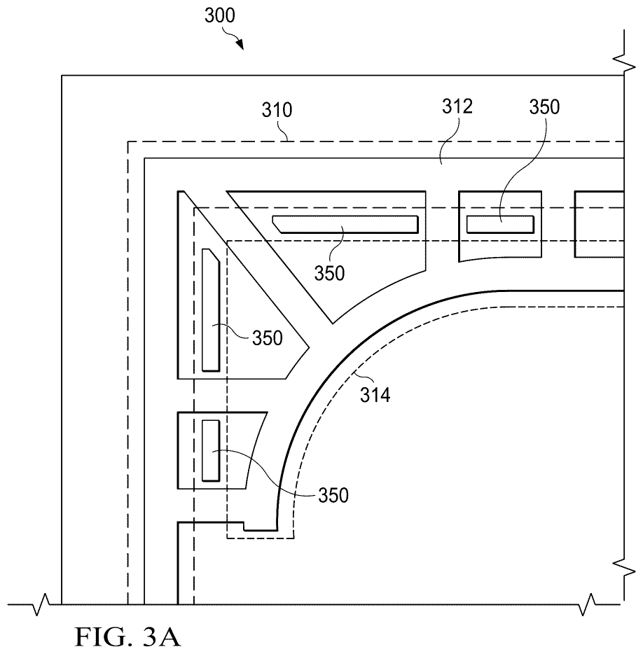

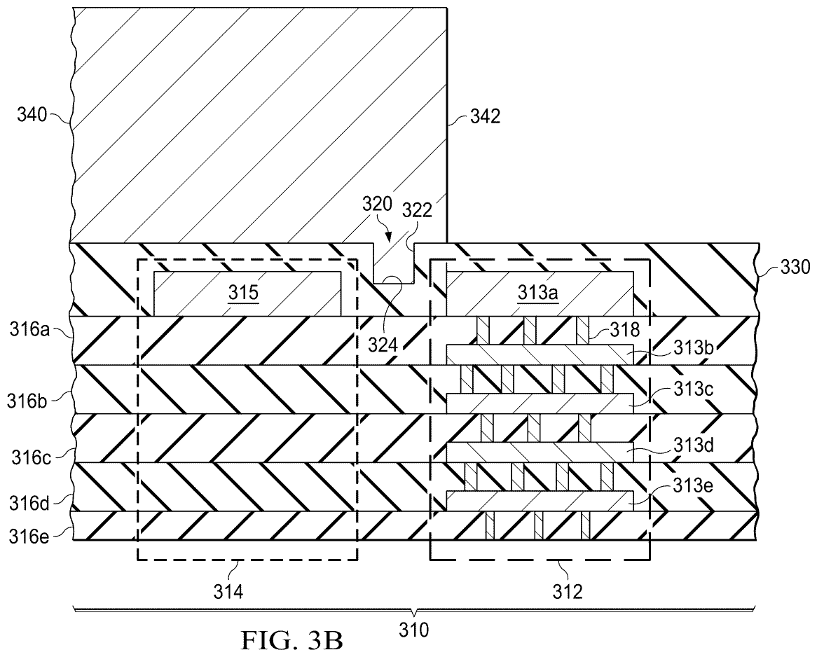

FIGS. 3A and 3B illustrate top and cross-sectional views, respectively, of a die seal layout design to improve adhesion of the polyimide layer to a passivation layer in semiconductor packaging, according to examples of the present disclosure. Semiconductor die 300 and may be located between scribe lines and integrated circuits of each die on a wafer.

Seal ring 310 may include outer seal ring 312 and inner seal ring 314. Outer seal ring 312 may be is formed by alternatively laminating dielectric layers 316 and metal layers 313, which are interconnected by vias 318 through dielectric layers 316. Inner seal ring 314 may be formed of metal layer 315 on dielectric layers 316. For example, outer seal ring 312 may be formed of five metal layers 313a, 313b, 313c, 313d, and 313e and inner seal ring 314 may have a single metal layer 315. Metal layer 313a and metal layer 315 may create mechanical support for trench 320 and polyimide layer 340 to anchor polyimide layer 340 to passivation layer 330. Additionally, the side bar of the top metal layer of outer seal ring 312 (i.e., metal layer 313a) may also hold metal layer 315 of inner seal ring 314 to prevent metal layer 315 from peeling off with polyimide layer 340 in the event polyimide layer 340 detaches from passivation layer 330. While inner seal ring 314 is shown in FIG. 3B as having one metal layer 315, inner seal ring 314 may have any number of metal layers 315 alternating with dielectric layers 316 and interconnected by vias.

The spacing between outer seal ring 312 and inner seal ring 314 may be based on the thickness of metal layer 315 of inner seal ring 314, the thickness of passivation layer 330, or any combination thereof. For example, as the thickness of passivation layer 330 increases, the spacing between outer seal ring 312 and inner seal ring 314 may also increase. In some examples, the spacing between outer seal ring 312 and inner seal ring 314 may be narrow (e.g., 1 to 10 microns (μm)).

Both outer seal ring 312 and inner seal ring 314 may be covered by passivation layer 330. As opposed to the non-planarized passivation layer 130 and 230 shown in FIGS. 1B and 2B, respectively, passivation layer 330 may be planarized.

Trench 320 may be created by adding one or more pad openings 350 between outer seal ring 312 and inner seal ring 314. The depth of trench 320 may be controlled by the pad mask and the over etch time, recipe, or any combination thereof used to create pad openings 350. While sidewalls 322 of trench 320 are shown in FIG. 3B as being at right angles to floor 324 of trench 320, sidewalls 322 may have a negative slope. The negative slope of sidewalls 322 may further increase the adhesion of polyimide layer 340 to passivation layer 330. The negative slope of sidewalls 322 may be created based on a deposition recipe of passivation layer 330, a slope of the side of metal layer 313a, a slope of the side of metal layer 315, an etic recipe for pad openings 350, or any combination thereof.

Polyimide layer 340 may be applied on top of passivation layer 330. Polyimide layer 340 may cover a portion of passivation layer 330. For example, polyimide layer 340 may cover a portion of passivation layer 330 and a portion of trench 320 but does not span the entirety of trench 320. Therefore, trench 320 may act as an anchor for polyimide layer 340 to adhere polyimide layer 340 to passivation layer 330, improving the adhesion of polyimide layer 340 to passivation layer 330. Boundary 342 of polyimide layer 340 in trench 320 may be adjusted to improve the adhesion of polyimide layer 340. For example, polyimide layer 3′40 may cover at least 50% of trench 320. In some examples, polyimide layer 340 may span trench 320 and overlap a portion of passivation layer 330 covering outer seal ring 312.

The grid structure of seal ring 310, including outer seal ring 312 and inner seal ring 314, may provide an array of anchor points to improve the adhesion of polyimide layer 340 to passivation layer 330. While FIG. 3A illustrates the grid structure in select locations along the perimeter of semiconductor die 300, the grid structure may extend along the entire perimeter of semiconductor die 300. In some examples, the grid structure may be interrupted by pad locations on semiconductor die 300.

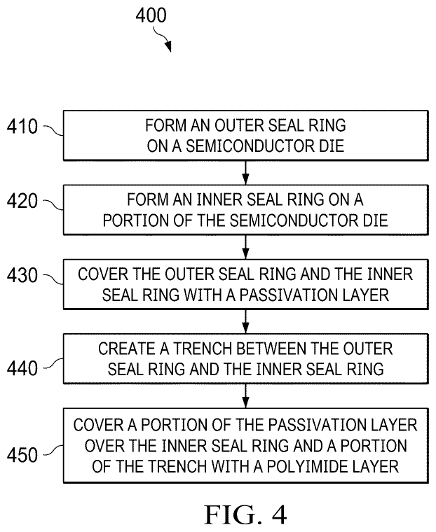

FIG. 4 illustrates a method performed for creating a die seal layout design to improve adhesion of a polyimide layer to a passivation layer in semiconductor packaging, according to examples of the present disclosure. Method 400 may be implemented using any suitable semiconductor packaging device designed to perform the functions disclosed herein or any other system operable to implement method 400. Although examples have been described above, other variations and examples may be made from this disclosure without departing from the spirit and scope of these disclosed examples.

Method 400 may begin at block 410 where an outer seal ring is formed on a semiconductor die. The outer seal ring may be the boundary or outermost part of the semiconductor die and may be located between scribe lines and integrated circuits of each die on a wafer. The outer seal ring may be is formed by alternatively laminating dielectric layers and metal layers, which are interconnected by vias through the dielectric layers. For example, the outer seal ring may be formed of five metal layers.

At block 420, an inner seal ring may be formed on a portion of the semiconductor die. The inner seal ring may be formed of one or more metal layers alternating with one or more dielectric layers interconnected by vias.

At block 430, the outer seal ring and the inner seal ring may be covered with a passivation layer. The passivation layer may be planarized or non-planarized. The passivation layer may be a thin layer that protects the active surface of a semiconductor from the surrounding environment.

At block 440, a trench may be created between the outer seal ring and the inner seal ring. For example, the passivation layer may follow the contours of the outer seal ring and the inner seal ring, creating a trench between the top metal layer of the outer seal ring and the top metal layer of the inner seal ring.

At block 450, a portion of the passivation layer over the inner seal ring and a portion of the trench may be covered with a polyimide layer. The polyimide layer may be applied on top of the passivation layer. The polyimide layer may cover a portion of the passivation layer. For example, the polyimide layer may cover a portion of the passivation layer and a portion of the trench but does not span the entirety of the trench. Therefore, the trench may act as an anchor for the polyimide layer to adhere the polyimide layer to the passivation layer, improving the adhesion of the polyimide layer to the passivation layer. The boundary of the polyimide layer in the trench may be adjusted to improve the adhesion of the polyimide layer. In some examples, the polyimide layer may span the trench and overlap a portion of the passivation layer covering the outer seal ring.

Although FIG. 4 discloses a particular number of operations related to method 400, method 400 may be executed with greater or fewer operations than those depicted in FIG. 4. In addition, although FIG. 4 discloses a certain order of operations to be taken with respect to method 400, the operations comprising method 400 may be completed in any suitable order.

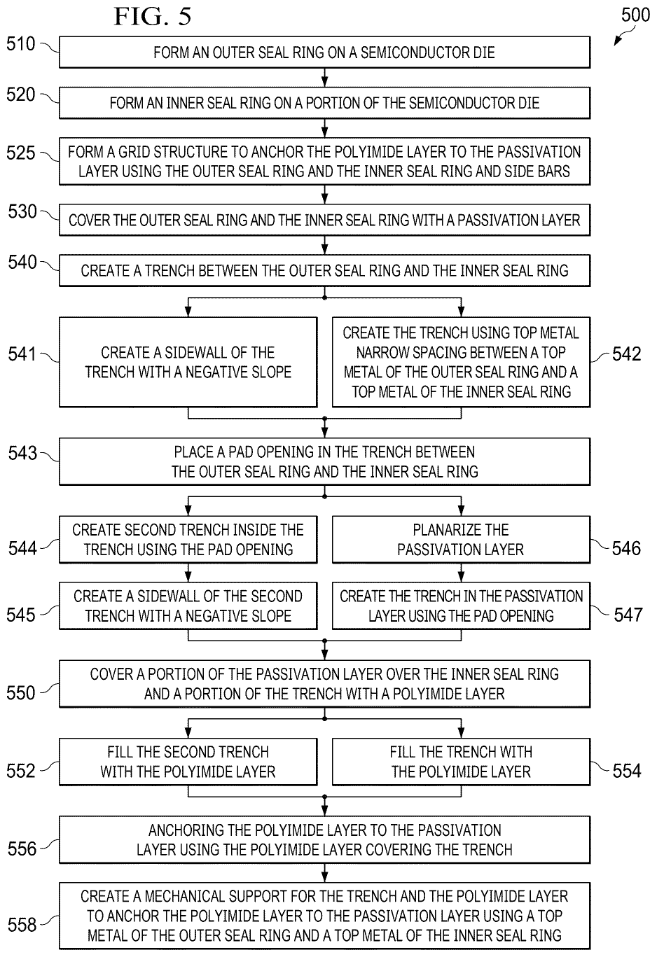

FIG. 5 illustrates a more detailed method performed for creating a die seal layout design to improve adhesion of a polyimide layer to a passivation layer in semiconductor packaging, according to examples of the present disclosure. Method 500 may be implemented using any suitable semiconductor packaging device designed to perform the functions disclosed herein or any other system operable to implement method 500. Although examples have been described above, other variations and examples may be made from this disclosure without departing from the spirit and scope of these disclosed examples.

Method 500 may begin at block 510 where an outer seal ring is formed on a semiconductor die. The outer seal ring may be the boundary or outermost part of the semiconductor die and may be located between scribe lines and integrated circuits of each die on a wafer. The outer seal ring may be is formed by alternatively laminating dielectric layers and metal layers, which are interconnected by vias through the dielectric layers. For example, the outer seal ring may be formed of five metal layers.

At block 520, an inner seal ring may be formed on a portion of the semiconductor die. The inner seal ring may be formed of one or more metal layers alternating with one or more dielectric layers interconnected by vias.

At block 525, a grid structure may be formed using the outer seal ring and the inner seal ring and side bars to anchor the polyimide layer to the passivation layer. Specifically, the grid structure may provide an array of anchor points to improve the adhesion of the polyimide layer to the passivation layer. The grid structure may be placed in select locations along the perimeter of the semiconductor die or may extend along the entire perimeter of the semiconductor die. In some examples, the grid structure may be interrupted by pad locations on the semiconductor die.

At block 530, the outer seal ring and the inner seal ring may be covered with a passivation layer. The passivation layer may be planarized or non-planarized. The passivation layer may be a thin layer that protects the active surface of a semiconductor from the surrounding environment.

At block 540, a trench may be created between the outer seal ring and the inner seal ring. For example, the passivation layer may follow the contours of the outer seal ring and the inner seal ring, creating a trench between the top metal layer of the outer seal ring and the top metal layer of the inner seal ring.

At block 541, a sidewall of the trench may be created with a negative slope. The negative slope of one or more sidewalls of the trench may further increase the adhesion of the polyimide layer to the passivation layer. The negative slope of one or more sidewalls may be created based on a deposition recipe of the passivation layer, a slope of the side of the top metal layer of the outer seal ring, a slope of the side of the top metal layer of the inner seal ring, or any combination thereof.

At block 542, the trench may be created using top metal narrow spacing between the top metal of the outer seal ring and the top metal of the inner seal ring. The spacing between the outer seal ring and the inner seal ring may be based on the thickness of the top metal layer of the inner seal ring, the thickness of the passivation layer, or any combination thereof. For example, as the thickness of the passivation layer increases, the spacing between the outer seal ring and the inner seal ring may also increase. In some examples, the spacing between the outer seal ring and the inner seal ring may be narrow (e.g., 1 to 10 microns (μm)).

At block 543, a pad opening may be placed in the trench between the outer seal ring and the inner seal ring. At block 544, a second trench may be created inside the trench using the pad opening. Specifically, the trench may be deepened by adding one or more pad openings between the outer seal ring and the inner seal ring. The pad openings may create a second trench and increase the depth of a portion of the trench. The depth of the second trench may be controlled by the pad mask and the over etch time, recipe, or any combination thereof used to create the pad openings.

At block 545, a sidewall of the second trench may be created with a negative slope. The negative slope of one or more sidewalls of the second trench may further increase the adhesion of the polyimide layer to the passivation layer. The negative slope of one or more sidewalls may be created based on a deposition recipe of the passivation layer.

At block 546, the passivation layer may be planarized. At block 547, the pad opening may create a trench in the passivation layer. The depth of the trench may be controlled by the pad mask and the over etch time, recipe, or any combination thereof used to create the pad openings. The negative slope of one or more sidewalls of the trench may further increase the adhesion of the polyimide layer to the passivation layer. The negative slope of one or more sidewalls may be created based on a deposition recipe of the passivation layer, a slope of the side of the top metal layer of the outer seal ring, a slope of the side of the top metal layer of the inner seal ring, or any combination thereof.

At block 550, a portion of the passivation layer over the inner seal ring and a portion of the trench may be covered with a polyimide layer. The polyimide layer may be applied on top of the passivation layer. The polyimide layer may cover a portion of the passivation layer. For example, the polyimide layer may cover a portion of the passivation layer and a portion of the trench but does not span the entirety of the trench. Therefore, the trench may act as an anchor for the polyimide layer to adhere the polyimide layer to the passivation layer, improving the adhesion of the polyimide layer to the passivation layer. The boundary of the polyimide layer in the trench may be adjusted to improve the adhesion of the polyimide layer. In some examples, the polyimide layer may span the trench and overlap a portion of the passivation layer covering the outer seal ring.

At block 552, the second trench created at block 544 may be filled with the polyimide layer. Filling the second trench with the polyimide layer may increase the adhesion of the polyimide layer to the passivation layer.

At block 554, the trench created at block 547 may be filled with the polyimide layer. In some examples, the polyimide layer may cover a portion of the trench and may not span the entirety of the trench. Therefore, the trench may act as an anchor for the polyimide layer to adhere the polyimide layer to the passivation layer, improving the adhesion of the polyimide layer to the passivation layer. The boundary of the polyimide layer in the trench may be adjusted to improve the adhesion of the polyimide layer. In some examples, the polyimide layer may span the trench and overlap a portion of the passivation layer covering the outer seal ring.

At block 556, a portion of the polyimide layer covering the portion of the trench may anchor the polyimide layer to the passivation layer. For example, the trench may act as an anchor for the polyimide layer to adhere the polyimide layer to the passivation layer, improving the adhesion of the polyimide layer to the passivation layer.

At block 558, a mechanical support for the trench and the polyimide layer to anchor the polyimide layer to the passivation layer may be created using a top metal of the outer seal ring and a top metal of the inner seal ring. For example, the top metal layer of the outer seal ring and top metal layer of the inner seal ring may create mechanical support for the trench and the polyimide layer to anchor the polyimide layer to the passivation layer. Additionally, the side bar of the top metal layer of the outer seal ring may also hold the top metal layer of the inner seal ring to prevent the top metal layer of the inner seal ring from peeling off with the polyimide layer in the event the polyimide layer detaches from the passivation layer.

Although FIG. 5 discloses a particular number of operations related to method 500, method 500 may be executed with greater or fewer operations than those depicted in FIG. 5. In addition, although FIG. 5 discloses a certain order of operations to be taken with respect to method 500, the operations comprising method 500 may be completed in any suitable order.

Although examples have been described above, other variations and examples may be made from this disclosure without departing from the spirit and scope of these disclosed examples.

1. An apparatus, comprising:
an outer seal ring on a semiconductor die;
an inner seal ring on a portion of the semiconductor die;
a trench between the outer seal ring and the inner seal ring;
a passivation layer covering the semiconductor die including the outer seal ring and the inner seal ring; and
a polyimide layer covering a portion of the passivation layer over the inner seal ring and a portion of the trench.

2. The apparatus of claim 1, wherein the trench is created using top metal narrow spacing between a top metal of the outer seal ring and a top metal of the inner seal ring.

3. The apparatus of claim 1, wherein a portion of the polyimide layer covering the portion of the trench anchors the polyimide layer to the passivation layer.

4. The apparatus of claim 1, wherein the outer seal ring and the inner seal ring and side bars form a grid structure to anchor the polyimide layer to the passivation layer.

5. The apparatus of claim 1, wherein a sidewall of the trench has a negative slope.

6. The apparatus of claim 1, comprising a pad opening in the trench between the outer seal ring and the inner seal ring.

7. The apparatus of claim 6, wherein the pad opening creates a second trench inside the trench.

8. The apparatus of claim 7, wherein the polyimide layer fills the second trench.

9. The apparatus of claim 7, wherein a sidewall of the second trench has a negative slope.

10. The apparatus of claim 6, wherein the passivation layer is planarized and the pad opening creates the trench in the passivation layer.

11. The apparatus of claim 10, wherein the polyimide layer fills the trench.

12. The apparatus of claim 10, wherein a top metal of the outer seal ring and a top metal of the inner seal ring creates a mechanical support for the trench and the polyimide layer to anchor the polyimide layer to the passivation layer.

13. A method, comprising:
forming an outer seal ring on a semiconductor die;
forming an inner seal ring on a portion of the semiconductor die;
covering the outer seal ring and the inner seal ring with a passivation layer;
creating a trench between the outer seal ring and the inner seal ring; and
covering a portion of the passivation layer over the inner seal ring and a portion of the trench with a polyimide layer.

14. The method of claim 13, comprising creating the trench using top metal narrow spacing between a top metal of the outer seal ring and a top metal of the inner seal ring.

15. The method of claim 13, wherein a portion of the polyimide layer covering the portion of the trench to anchor the polyimide layer to the passivation layer.

16. The method of claim 13, comprising forming a grid structure to anchor the polyimide layer to the passivation layer using the outer seal ring and the inner seal ring and side bars.

17. The method of claim 13, wherein a sidewall of the trench has a negative slope.

18. The method of claim 13, comprising placing a pad opening in the trench between the outer seal ring and the inner seal ring.

19. The method of claim 18, comprising creating a second trench inside the trench using the pad opening.

20. The method of claim 19, comprising filling the second trench with the polyimide layer.

21. The method of claim 19, wherein a sidewall of the second trench has a negative slope.

22. The method of claim 18, wherein the passivation layer is planarized and the pad opening creates the trench in the passivation layer.

23. The method of claim 22, comprising filling the trench with the polyimide layer.

24. The method of claim 22, comprising creating a mechanical support for the trench and the polyimide layer to anchor the polyimide layer to the passivation layer using a top metal of the outer seal ring and a top metal of the inner seal ring.
